(19) United States
(12) Patent Application Publication
(10) Pub. No.: US 2023/0327312 A1
(43) Pub. Date: Oct. 12, 2023

(54) RADIO FREQUENCY POWER DIVIDER AND CIRCUIT INCLUDING THE SAME

(71) Applicant: Telefonaktiebolaget LM Ericsson (publ), Stockholm (SE)

(72) Inventors: Xiaoqin Zhang, Nanjing (CN); Jun Ding, Nanjing (CN); Linxiang Zhan, Nanjing (CN); Hairong Xie, Nanjing (CN); Qian Wan, Nanjing (CN)

(21) Appl. No.: 18/024,096

(22) PCT Filed: Sep. 1, 2020
(86) PCT No.: PCT/CN2020/112871

§ 371 Date: Mar. 1, 2023

(51) Int. Cl. H01P 5/16; H03F 1/02; H03F 3/21

(52) U.S. Cl. CPC H01P 5/16; H03F 1/0288; H03F 3/211

(57) ABSTRACT

The present disclosure relates to a power divider and a circuit including the same. The power divider may comprise: at least two branches; the at least two branches comprise a first branch coupled between a first port and a second port; and a second branch coupled between the first port and a third port; the first branch comprises a first transmission line for power dividing function coupled to the first port, and a first impedance matching structure coupled to the second port; and the second branch comprises a second transmission line for power dividing function coupled to the first port, and a second impedance matching structure coupled to the third port. According to embodiments of the present disclosure, lengths and/or even types of the transmission lines in the power divider may be reduced.

### TECHNICAL FIELD

The present disclosure relates generally to the electric circuitry technology, and in particular, to a radio frequency power divider and a circuit including the same.

### BACKGROUND

This section introduces aspects that may facilitate better understanding of the present disclosure. Accordingly, the statements of this section are to be read in this light and are not to be understood as admissions about what is in the prior art or what is not in the prior art.

In many radio frequency, RF, circuits, a power divider may be used to divide power from the same (source) port to different (reception) ports. Sometimes, it may also work conversely to combine power form different source ports to one reception port. Usually, the power divider comprises transmission lines with certain lengths for different functionalities.

### SUMMARY

Certain aspects of the present disclosure and their embodiments may provide solutions to these or other challenges. There are, proposed herein, various embodiments which address one or more of the issues disclosed herein.

Conventionally, functionalities of the power divider, such as power dividing, impedance transforming and/or offsetting, are implemented by transmission lines with certain lengths in different function portions of the power divider. Transmission lines in each portion are designed independently according to each functionality, and thus the lengths thereof are hard to be reduced. Therefore, the overall size of the power divider is hard to be reduced.

Certain aspects of the present disclosure and their embodiments may provide solutions to these or other challenges. There are, proposed herein, various embodiments which address one or more of the issues disclosed herein. According to embodiments of the present disclosure, an improved power divider and a circuit including the same are provide to reduce lengths and/or even types of the transmission lines in the power divider, and thus to reduce the overall size of the power divider and the circuit including the same.

A first aspect of the present disclosure provides a power divider, comprising: at least two branches. The at least two branches comprise a first branch coupled between a first port and a second port; and a second branch coupled between the first port and a third port. The first branch comprises a first transmission line for power dividing function coupled to the first port, and a first impedance matching structure coupled to the second port. The second branch comprises a second transmission line for power dividing function coupled to the first port, and a second impedance matching structure coupled to the third port.

In embodiments of the present disclosure, the first impedance matching structure is constructed at least based on an impedance matching requirement of a first circuit portion following the second port. The second impedance matching structure is constructed at least based on an impedance matching requirement of a second circuit portion following the third port.

In embodiments of the present disclosure, the first impedance matching structure is further constructed to provide impedance transforming between the first transmission line and the first circuit portion. The second impedance matching structure is further constructed to provide impedance transforming between the second transmission line and the second circuit portion.

In embodiments of the present disclosure, the first circuit portion and/or the second circuit portion comprise a power amplifying component.

In embodiments of the present disclosure, the power amplifying component comprises a transistor.

In embodiments of the present disclosure, the first impedance matching structure and/or the second impedance matching structure have a planar shape.

In embodiments of the present disclosure, the first impedance matching structure and/or the second impedance matching structure have a rectangle shape with a width lager than a width of the first transmission line and/or the second transmission line.

In embodiments of the present disclosure, an impedance of the first transmission line and an impedance of the second transmission line are determined based at least on a power dividing ratio between the second port and the third port.

In embodiments of the present disclosure, the power divider is a Wilkinson power divider, WPD.

A second aspect of the present disclosure provides a circuit, comprising the power divider according to any of embodiments according to the first aspect of the present disclosure.

In embodiments of the present disclosure, the circuit is a Doherty power amplifier. The power divider functions as an input power splitter of the Doherty power amplifier. The Doherty power amplifier comprises a first amplifying transistor coupled to the second port, and a second amplifying transistor coupled to the third port. The first amplifying transistor has an offsetting requirement for the first branch of the power divider.

In embodiments of the present disclosure, the first branch further comprises a third transmission line for offsetting function, coupled between the first transmission line and the first impedance matching structure.

In embodiments of the present disclosure, the third transmission line is constructed at least based on the offsetting requirement of the first amplifying transistor.

In embodiments of the present disclosure, the third transmission line is further constructed to provide impedance transforming between the first transmission line and the first amplifying transistor.

In embodiments of the present disclosure, the circuit is a power combining circuit. The power divider functions as an input power splitter of the power combining circuit. The power combining circuit comprises a third amplifying transistor coupled to the second port, and a fourth amplifying transistor coupled to the third port.

Embodiments herein afford many advantages. For example, in embodiments herein, lengths and/or even types of the transmission lines in the power divider may be reduced, and thus the overall size of the power divider and the circuit including the same may be further reduced. A person skilled in the art will recognize additional features and advantages upon reading the following detailed description.

### BRIEF DESCRIPTION OF DRAWINGS

Through the more detailed description of some embodiments of the present disclosure in the accompanying drawings, the above and other objects, features and advantages of the present disclosure will become more apparent, wherein the same reference generally refers to the same components in the embodiments of the present disclosure.

FIG. 1 is an exemplary circuit principle diagram of a power divider.

FIG. 2 is an exemplary circuit principle diagram of a circuit including the power divider as shown in FIG. 1.

FIG. 3 is another exemplary circuit principle diagram of a circuit including the power divider as shown in FIG. 1.

FIG. 4 is an exemplary circuit principle diagram of a power divider, according to embodiments of the present disclosure.

FIG. 5 is an exemplary circuit principle diagram of a circuit including the power divider as shown in FIG. 4, according to embodiments of the present disclosure.

FIG. 6 is another exemplary circuit principle diagram of a circuit including the power divider as shown in FIG. 4, according to embodiments of the present disclosure.

FIG. 7 is an exemplary layout diagram of the power divider in FIG. 1, for comparison with the embodiments of the present disclosure.

FIG. 8 is an amplitude diagram for the exemplary conventional WPD as shown in FIG. 7.

FIG. 9 is a phase diagram for the exemplary conventional WPD as shown in FIG. 7.

FIG. 10 is an exemplary layout diagram of the WPD according to embodiments of the present disclosure.

FIG. 11 is an amplitude diagram for the exemplary WPD as shown in FIG. 10.

FIG. 12 is a phase diagram for the exemplary WPD as shown in FIG. 10.

### DETAILED DESCRIPTION

Some of the embodiments contemplated herein will now be described more fully with reference to the accompanying drawings. Other embodiments, however, are contained within the scope of the subject matter disclosed herein, the disclosed subject matter should not be construed as limited to only the embodiments set forth herein; rather, these embodiments are provided by way of example to convey the scope of the subject matter to those skilled in the art.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Furthermore, the described features, advantages, and characteristics of the disclosure may be combined in any suitable manner in one or more embodiments. One skilled in the relevant art will recognize that the disclosure may be practiced without one or more of the specific features or advantages of a particular embodiment. In other instances, additional features and advantages may be recognized in certain embodiments that may not be present in all embodiments of the disclosure.

As used herein, the terms “first”, “second” and so forth refer to different elements. The singular forms “a” and “an” are intended to include the plural forms as well, unless the context clearly indicates otherwise. The terms “comprises”, “comprising”, “has”, “having”, “includes” and/or “including” as used herein, specify the presence of stated features, elements, and/or components and the like, but do not preclude the presence or addition of one or more other features, elements, components and/or combinations thereof. The term “based on” is to be read as “based at least in part on”. The term “one embodiment” and “an embodiment” are to be read as “at least one embodiment”. The term “another embodiment” is to be read as “at least one other embodiment”. Other definitions, explicit and implicit, may be included below.

It is noted that these terms as used in this document are used only for ease of description and differentiation among nodes, devices or networks etc. With the development of the technology, other terms with the similar/same meanings may also be used.

In the following description and claims, unless defined otherwise, all technical and scientific terms used herein have the same meaning as commonly understood by one of ordinary skills in the art to which this disclosure belongs.

A power divider is a fundamental component in microwave system, and is used for dividing the input signal into two or more signals. However, it typically takes up much room due to its quarter-wave transformers, particularly these emerging in unequal cases.

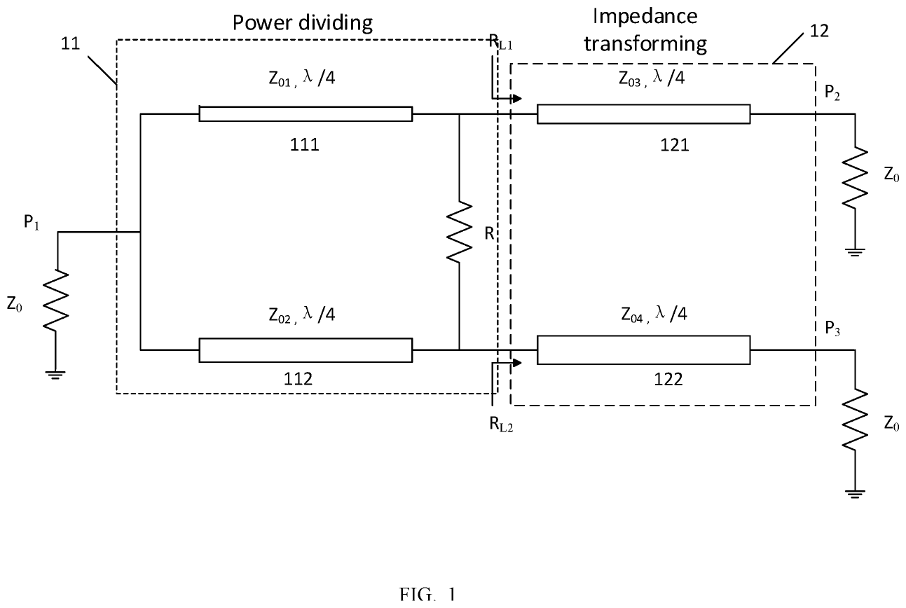

FIG. 1 is an exemplary circuit principle diagram of a power divider.

The Wilkinson power divider (WPD), proposed by E. Wilkinson in 1960, is one of the most commonly used components because of its simple design and structures. Wilkinson power dividers (WPDs) are widely used in microwave (Doherty) power amplifiers ((D)PAs), power combining circuits, mixers, feeding networks in antenna arrays for microwave and millimeter systems. Particularly, unequal WPDs often find applications in Doherty circuits as the power dividing/splitting network.

A conventional Wilkinson power divider (WPD) is shown in FIG. 1, and it comprises a power dividing/distribution network 11 and a quarter-wave impedance transforming network 12. Each network includes a plurality of quarter-wave (λ/4) transmission lines.

The power from the port 1 may be divided to the port 2 and port 3, with a predesigned ratio. The structure of conventional WPD in FIG. 1 consists of four quarter-wave transmission lines, TLs, two of them serve as power dividing network, and two of them act as impedance transforming. Specifically, a branch from the port P1 to the port P2 may comprise a transmission line 111 for power dividing function coupled to the port P1, and a transmission line 121 for impedance transforming function coupled between the transmission line 111 and the port P2.

Another branch from the port P1 to the port P3 may comprise a transmission line 112, coupled to the port P1, for power dividing function, and a transmission line 122, coupled between the transmission line 112 and the port P3, for impedance transforming function.

In the FIG. 1, Z₀ refers to a typical port impedance after matching, such as 50 Ohm. Z₀₁, Z₀₂, Z₀₃, Z₀₄ respectively represent characteristic impedances of the transmission line 111, transmission line 112, transmission line 121, and transmission line 122.

R refers to an isolation impedance between two branches, and it is usually implemented by a physical design (spatial size, material between two branches, etc.) of a print circuit board, PCB, carrying the WPD. R_{L1}, R_{L2} respectively represent equivalent impedances provided by the transmission lines 121, 122, as a load impedance to the side of the transmission lines 111, 112.

As mentioned above, typically, conventional unequal WPD takes up much space due to its output quarter-wave transformers, which leads to higher path loss and thus restricts its application in practice.

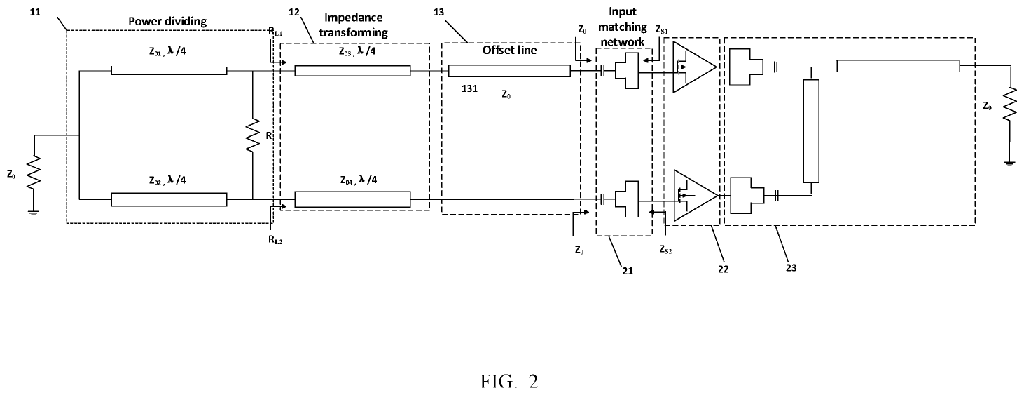

FIG. 2 is an exemplary circuit principle diagram of a circuit including the power divider as shown in FIG. 1.

As an illustrative example, one microstrip −2 dB WPD operating in B3 band i.e. 1805-1880 MHz, with application to Doherty power amplifier, PA, is considered here, though the WPD can be applied to other power combining applications. Here a transistor available in market with a type of “Ampleon BLC 9G 20LS-470AVT” is selected for Doherty PA, whose Z_{S} for Carrier and Peaking transistors at center frequency are Z_{S1}=( 2.10−j*4.50) Ohm and Z_{S2}=(1.89−j*5.55) Ohm respectively (such data may be obtained from a loadpull procedure/test, or just according to handbook or design reference).

It should be understood, the WPD may operate in any other frequency band, such as 758-803 MHz, 859-894 MHz, 935-960 MHz, 1805-1880 MHz.

As shown in FIG. 2, a transmission line/offset line 131 serves as offsetting network 13, which is required by the Doherty PA. Further, an input matching network 21 provide impedance matching function between WPD and amplifying components 22, such as the amplifying transistors. An exemplary combiner structure 23 is also shown.

It can be seen that, when a WPD with the offset line is used in Doherty, too much room may be occupied, since the quarter-wave impedance transforming sections in unequal WPD occupy too much space and then increase path loss.

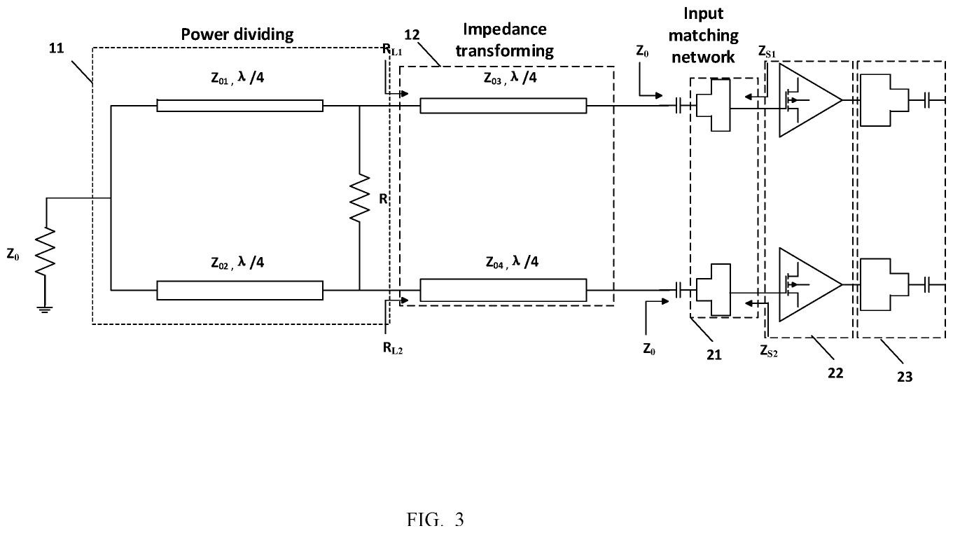

FIG. 3 is another exemplary circuit principle diagram of a circuit including the power divider as shown in FIG. 1.

As shown in FIG. 3, the offset line may be not necessary in an application for the WPD in a power combining circuit. However, the quarter-wave impedance transforming sections still occupy too much space and then increase path loss.

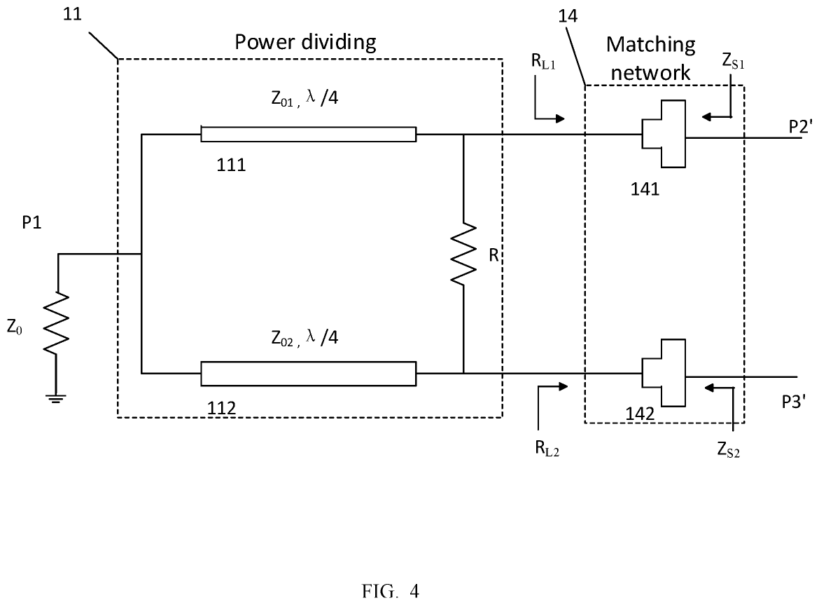

FIG. 4 is an exemplary circuit principle diagram of a power divider, according to embodiments of the present disclosure.

As shown in FIG. 4, the power divider may comprise: at least two branches. The at least two branches comprise a first branch coupled between a first port P1 and a second port P2′; and a second branch coupled between the first port P1 and a third port P3′. The first branch comprises a first transmission line 111 for power dividing function coupled to the first port P1, and a first impedance matching structure 141 coupled to the second port P2′. The second branch comprises a second transmission line 112 for power dividing function coupled to the first port P1, and a second impedance matching structure 142 coupled to the third port P3′.

In embodiments of the present disclosure, the power divider is a Wilkinson power divider, WPD.

In embodiments of the present disclosure, an impedance Z₀₁ of the first transmission line 111 and an impedance Z₀₂ of the second transmission line 112 are determined based at least on a power dividing ratio between the second port P2′ and the third port P3′.

The first transmission line 111 and the second transmission line 112 may be basically the same as in the conventional WPD, as shown in FIG. 1.

In embodiments of the present disclosure, the first impedance matching structure 141 is constructed at least based on an impedance matching requirement of a first circuit portion following the second port P2′. The impedance matching requirement of the first circuit portion following the second port P2′ may be presented by the Z_{S1}, namely, as a source impedance to the following first circuit portion. The second impedance matching structure 142 is constructed at least based on an impedance matching requirement of a second circuit portion following the third port P3′. Similarly, the impedance matching requirement of the second circuit portion following the third port P3′ may be presented by the Z_{S2}.

In embodiments of the present disclosure, the first impedance matching structure 141 is further constructed to provide impedance transforming between the first transmission line 111 and the first circuit portion. The second impedance matching structure 142 is further constructed to provide impedance transforming between the second transmission line and the second circuit portion.

Namely, as load impedances to the side of the first transmission line 111, and the second transmission line 112 respectively, the first impedance matching structure 141 may present an impedance of R_{L1}, and the second impedance matching structure 142 may present an impedance of R_{L2}.

In embodiments of the present disclosure, the first impedance matching structure 141 and/or the second impedance matching structure 142 have a planar shape.

In embodiments of the present disclosure, the first impedance matching structure 141 and/or the second impedance matching structure 142 have a rectangle shape with a width lager than a width of the first transmission line 111 and/or the second transmission line 112.

According to embodiments of the present disclosure, an impedance matching network 14 including impedance matching structures in the proposed WPD is utilized to replace an impedance transforming network 12 of the conventional WPD in the FIG. 1. The room occupied by the impedance transforming network 12 may be reduced.

In embodiments of the present disclosure, the first circuit portion and/or the second circuit portion comprise a power amplifying component, such as for power amplifier or power combing circuit, etc.

In embodiments of the present disclosure, the power amplifying component comprises a transistor.

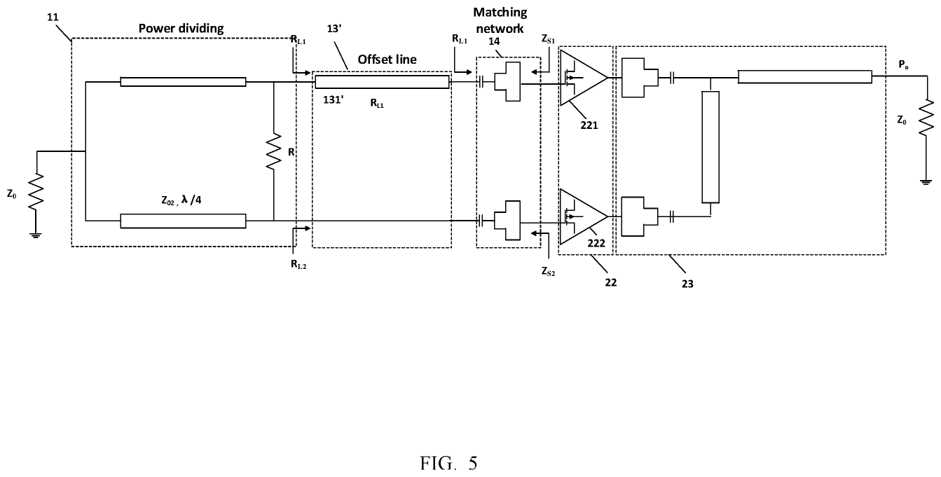

FIG. 5 is an exemplary circuit principle diagram of a circuit including the power divider as shown in FIG. 4, according to embodiments of the present disclosure.

As shown in FIG. 5, the circuit may comprise the power divider according to any of embodiments described above.

In embodiments of the present disclosure, the circuit is a Doherty power amplifier. The power divider functions as an input power splitter of the Doherty power amplifier. The Doherty power amplifier comprises a first amplifying transistor 221 coupled to the second port, and a second amplifying transistor 222 coupled to the third port. The first amplifying transistor 221 has an offsetting requirement for the first branch of the power divider.

The first amplifying transistor 221 and the second amplifying transistor 222 may form an amplifying network. The Doherty power amplifier may further comprise an output network 23, for power combining, output impedance matching, etc.

In embodiments of the present disclosure, the first branch further comprises a third transmission line 131′ for offsetting function of the offsetting network 13′, coupled between the first transmission line 111 and the first impedance matching structure 141.

In embodiments of the present disclosure, the third transmission line 131′ is constructed at least based on the offsetting requirement of the first amplifying transistor 221.

In embodiments of the present disclosure, the third transmission line 131′ is further constructed to provide impedance transforming between the first transmission line 111 and the first amplifying transistor 221.

According to embodiments of the present disclosure, the impedance transforming network 12, the offsetting network 13 and the input matching network 21 in FIG. 2 are replaced by the offsetting network 13′ and the matching network 14 in FIG. 5. The impedance transforming network 12 is totally reduced/cancelled, while the size of the offsetting network, and the matching network are still similar. Thus, the overall size of the circuit, such as the Doherty power amplifier, including the WPD are reduced significantly.

FIG. 6 is another exemplary circuit principle diagram of a circuit including the power divider as shown in FIG. 4, according to embodiments of the present disclosure.

In embodiments of the present disclosure, the circuit is a power combining circuit. The power divider functions as an input power splitter of the power combining circuit. The power combining circuit comprises a third amplifying transistor coupled to the second port, and a fourth amplifying transistor coupled to the third port.

As shown in FIG. 6, the offset line may be not necessary in an application for the WPD in a power combining circuit. The quarter-wave impedance transforming sections (impedance transforming network 12) occupying too much space as shown in FIG. 3 are still reduced/cancelled, while the size of the matching network is still similar. Thus, the overall size of the circuit, such as a power combining circuit, including the WPD are reduced significantly.

Following equations may be used to design (electric and/or physical) characteristics of each part in the FIG. 1-6.

$${k}^{2} = \frac{{P}_{3}}{{P}_{2}}$$

$${Z}_{01} = {Z}_{0} \sqrt{k ( 1 + {k}^{2} )}$$

$${Z}_{02} = {Z}_{0} \sqrt{\frac{1 + {k}^{2}}{{k}^{3}}}$$

$$R = {Z}_{0} ( k + \frac{1}{k} )$$

$${Z}_{03} = {Z}_{0} \sqrt{k}$$

$${Z}_{04} = {Z}_{0} / \sqrt{k}$$

$${R}_{L 1} = k {Z}_{0}$$

$${R}_{L 2} = {Z}_{0} / k$$

wherein, k²=P₃/P₂ is the known power ratio between ports 2 and 3. R is the isolation resistor between two output ports. Two quarter-wave matching transformers with impedance Z₀₃ and Z₀₄ are used to transform output impedances to the impedance Z₀.

For a case of a power ratio of P2 to P3=1:1.71 and Z₀=50Ω, it is calculated that: k=1.30756, Z₀₁=94.12Ω, Z₀₂=55.05Ω, R=103.6Ω, Z₀₃=57.17Ω, Z₀₄=43.73Ω, R_{L1}=65.38Ω, R_{L2}=38.24Ω.

Namely, for a given Z₀, a given power ratio (and thus a given k), the Z₀₁, Z₀₂, R, Z₀₃, Z₀₄, R_{L1}, R_{L2} will be determined accordingly at first. Further, Z₀₁, Z₀₂, Z₀₃, Z₀₄ are directly used as characteristic impedances for transmission line.

Particularly, concerning the first impedance matching structure 141 and the second impedance matching structure 142 of the matching network 14 in FIG. 4-6, the impedance of them may be further determined by the requirements of the Zₛ₁, R_{L1}, Zₛ₂, R_{L2}.

Accordingly, as an example of the first impedance matching structure 141, its impedance as a source side may be presented as Z_{S}=(R_{S}+jX_{S})=(R_{L1})*=(65.38)*=65.38Ω, and its impedance as a load side may be presented as Z_{L}=(R_{L}+jX_{L})=(Z_{S1})*=(2.10−j*4.50)*=(2.10+j*4.50)Ω, according to exemplary parameter values described above. ( )* means a conjugate calculation. That is, for the first impedance matching structure 141, its source impedance Zₛ is the impedance seen towards the input end, so it is equivalent to (R_{L1})* in FIG. 4, and its load impedance Z_{L} is the impedance seen from itself to the output end, so it is equivalent to (Z_{S1})* in FIG. 4, and * denotes conjugation, because usually a conjugate matching is referred to. Therefore, the R_{S}=65.38, X_{S}=0, R_{L}=2.10, X_{L}=4.50.

Then, parameters (Z_{T}, θ) of the matching structure may be further determined by following formulas:

$${Z}_{T} = \sqrt{\frac{{R}_{L} ( {R}_{S}^{2} + {X}_{S}^{2} ) - {R}_{S} ( {R}_{L}^{2} + {X}_{L}^{2} )}{{R}_{S} - {R}_{L}}}$$

$$θ = {tan}^{- 1} [ \frac{{Z}_{T} ( {R}_{L} - {R}_{S} )}{{R}_{L} {X}_{S} - {X}_{L} {R}_{S}} ]$$

wherein, Z_{T} may be a characteristic impedance, and θ is the electrical length of the matching structure, tan⁻¹ is inverse tangent function.

This is, to match the Zₛ₁ and R_{L1} requirement to the first matching structure 141 including a single transmission line (with characteristic impedance Z_{T} and electrical length θ), the above formula is used. Of course, the matching network can also be realized in any other ways. The calculation procedure for the second matching structure 142 is just the same to the first matching structure 141.

Here Zₛ means the source impedance (R_{S} for source resistance, X_{S} for source reactance) and Z_{L} means the load impedance (R_{L} for load resistance, X_{L} for load reactance).

Further, the width and length of each involved microstrip section for the transmission lines and/or impedance matching network, are calculated by following formulas, based on such characteristic impedance and the electrical length (Z_{T}, θ):

$$Z = \frac{120 π Ω}{\sqrt{{ε}_{e}} [ {W}^{′} / h + 1.393 + 0.667 ln ( {W}^{′} / h + 1.444 ) ]}$$

$${ε}_{e} = \frac{{ε}_{r} + 1}{2} + \frac{{ε}_{r} - 1}{2} \frac{1}{\sqrt{1 + 12 h / W}} - \frac{{ε}_{r} - 1}{4.6} \frac{t / h}{\sqrt{W / h}}$$

$$\frac{{W}^{′}}{h} = \frac{W}{h} + \frac{1.25}{π} \frac{t}{h} ( 1 + ln \frac{2 h}{t} )$$

$$L = \frac{λ}{4} = \frac{\frac{v}{f}}{4} = \frac{\frac{1}{\sqrt{μ ε}}}{4 f} = \frac{\frac{c}{\sqrt{{μ}_{γ} {ε}_{e}}}}{4 f}$$

$$θ = \frac{2 π}{λ} L ⇒ L = \frac{c θ}{{f}_{0} \sqrt{{μ}_{r} {ε}_{e}} 2 π}$$

wherein, Z is the characteristic impedance of the microstrip, W is the width of microstrip line, and L is its length. εᵣ is the relative dielectric constant of PCB substrate, and =3.66 for a product Rogers 4350b available in the market, εₑ is the effective dielectric constant of a microstrip line, and h is the thickness of PCB substrate and may be 0.762 mm (for example h=30 mil=0.762 mm), t is the thickness of microstrip, typically 35 um. W′ is an intermediate variant for calculating; π is a circumference ratio, Ω is the unit “Ohm”, v is the transmission speed of the electric signal, c is a known transmission speed of the light, μ is a magnetic permeability, ε is a dielectric constant, ln is a logarithmic function with a base of the constant “e”, f is a frequency, λ is a wave length, μᵣ is known relative magnetic permeability, and =1 in this embodiment. f₀ is a known center frequency, and is 1842.5 MHz in this embodiment.

The above formulas may be general for all involved microstrip sections, for example, for the first transmission line 111 as shown in FIG. 4, 5, Z₀₁=94.12Ω, θ=90°, thus, a length may be about L1=25.4 mm, and a width may be about W1=0.44 mm.

For the third transmission line 131′ as shown in FIG. 5, R_{L1}=65.38Ω, θ=90°, thus, a width may be W9=1 mm, and a length may be L9=24.7 mm.

For the first matching structure 141, Z_{S1}=(2.10−j*4.50)Ω, determined based on a handbook of the selected transistor, and R_{L1}=65.38Ω as calculated above. Then, it is calculated that Z_{T}=10.79Ω, θ=66.7°. Further, it is calculated that W7=11.7 mm, L7=16.5 mm.

Each section of the second branch of the power divider and the circuit including the power divider may be also calculated in the same way.

Of course, these physical dimensions can be obtained by aid of commercial software like ADS (advanced design system), Ansoft designer and AWR (Applied Wave Research).

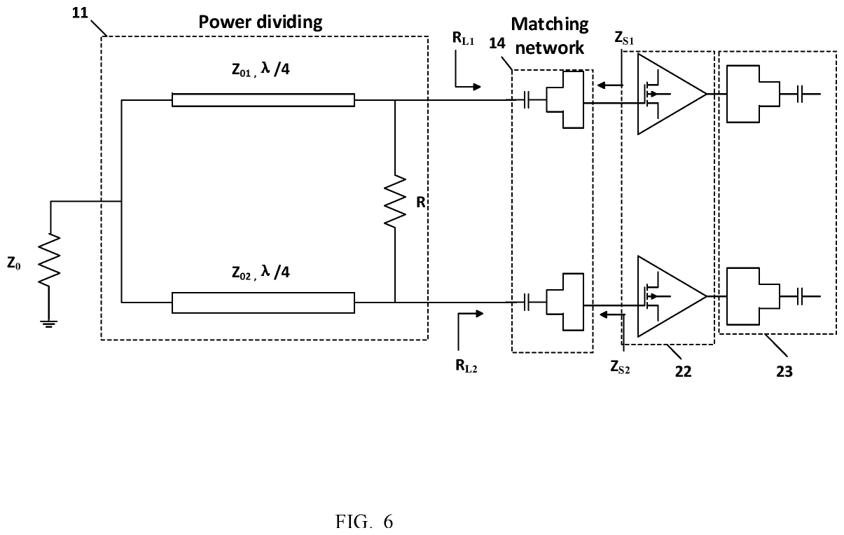

FIG. 7 is an exemplary layout diagram of the power divider in FIG. 1, for comparison with the embodiments of the present disclosure.

As shown in the FIG. 7, a width W₁, and lengths L₁₁, L₁₂, and L₁₃ are for the first transmission line 111. A width W₂, and lengths L₂₁, L₂₂, and L₂₃ are for the second transmission line 112. A width W₃ and a length L₃ are for the transmission line 121 for impedance transforming. A width W₄ and a length L₄ are for the transmission line 122 for impedance transforming. A length L₀₁ is for a transmission line 131 for offsetting. The part with the width W₀ and the length of d does not influence the electric characteristics, and it is arranged for the purpose of better layout pattern. W₅, W₆, L₅, L₆ are for input matching network of the Doherty power amplifier.

TABLE 1
Optimized dimensions of conventional configuration.

| Parameter | W₀ | W₁ | L₁₁ | L₁₂ | L₁₃ | W₂ | L₂₁ | L₂₂ | L₂₃ | W₃ |
|---|---|---|---|---|---|---|---|---|---|---|
| Unit (mm) | 1.62 | 0.44 | 8 | 10 | 6.5 | 1.38 | 10 | 10 | 8.5 | 1.29 |
| Parameter | L₃ | W₄ | L₄ | L₀₁ | d | W₅ | L₅ | W₆ | L₆ | |
| Unit (mm) | 24 | 2 | 23.5 | 27 | 8 | 13.5 | 13 | 14 | 12 | |

It can be seen form the table 1 and the FIG. 7, transmission lines 121, 122 for impedance transforming occupy much space.

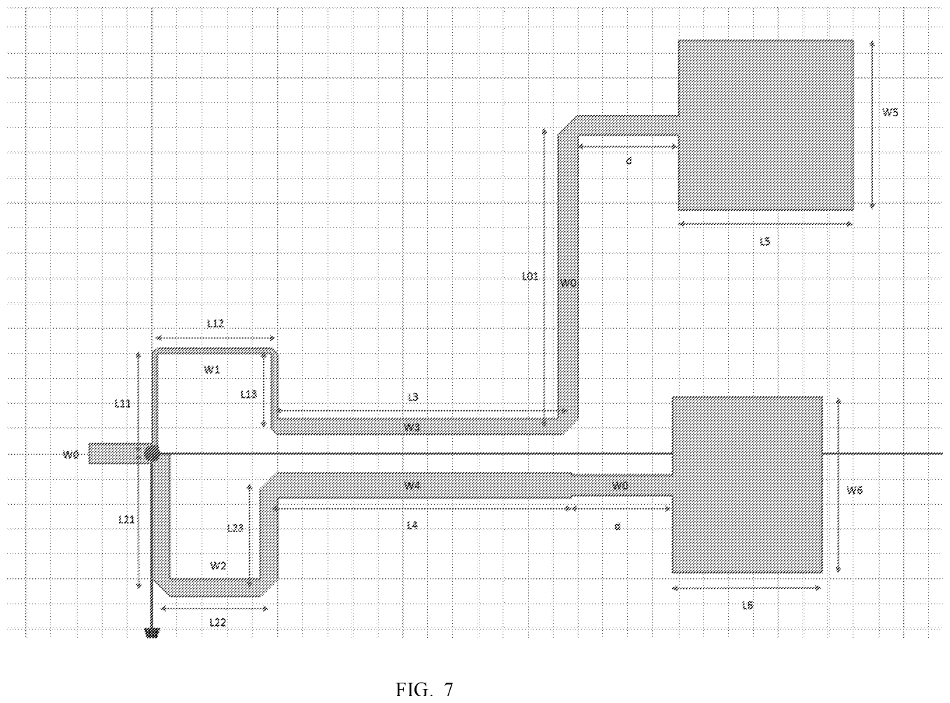

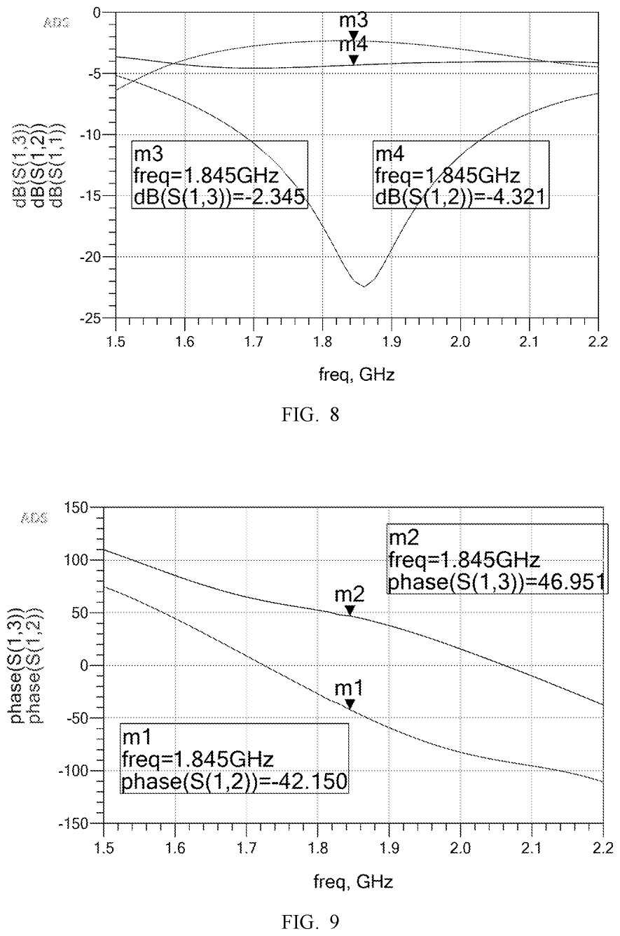

FIG. 8 is an amplitude diagram for the exemplary conventional WPD as shown in FIG. 7.

The curves dB(S1,3), dB(S1,2), dB(S1,1) mean a power portion from port P1 to port P3 (P3′), a power portion from port P1 to port P2 (P2′), and an input return loss at port1, respectively. The unit for them is “dB”.

Two probes on the curves are shown. m3 is a probe on the curve dB(S1,3), and indicates the frequency 1.845 GHz, and a value of dB(S1,3) of −2.345. m4 is a probe on the curve dB(S1,2), and indicates the frequency 1.845 GHz, and a value of dB(S1,2) of −4.321.

FIG. 9 is a phase diagram for the exemplary conventional WPD as shown in FIG. 7.

The curves phase(S1,3), phase (S1,2) mean a transmission phase from port P1 to port P3 (P3′), and a transmission phase from port P1 to port P2 (P2′), respectively. The unit for them is “degree” (“°”).

Two probes on the curves are shown. m1 is a probe on the curve phase (S1,2), and indicates the frequency 1.845 GHz, and a value of phase (S1,2) of −42.150. m2 is a probe on the curve phase (S1,3), and indicates the frequency 1.845 GHz, and a value of phase (S1,3) of 46.951.

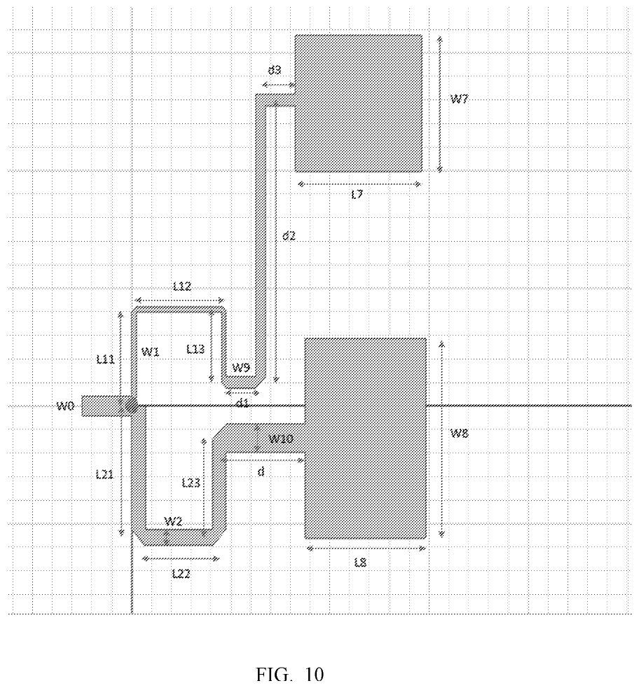

FIG. 10 is an exemplary layout diagram of the WPD according to embodiments of the present disclosure.

As shown in the FIG. 10, a width W₁, and lengths L₁₁, L₁₂, and L₁₃ are for the first transmission line 111. A width W₂, and lengths L₂₁, L₂₂, and L₂₃ are for the second transmission line 112. A width W₉, and lengths d₁, d₂, d₃ are for a transmission line 131′ for offsetting. A width W₁₀, with a length of d may not influence the electric characteristic, and it is just arranged for layout pattern. W₇, W₈, L₇, L₈ are for matching structures 141, 142 of the WPD.

TABLE 2
Optimized dimensions of the proposed microstrip WPD with
impedance matching structures for Doherty Input matching.

| Parameter | W₀ | W₁ | L₁₁ | L₁₂ | L₁₃ | W₂ | L₂₁ | L₂₂ | L₂₃ |
|---|---|---|---|---|---|---|---|---|---|
| Unit (mm) | 1.62 | 0.44 | 8 | 9.5 | 6.5 | 1.38 | 10.5 | 9.5 | 9 |
| Parameter | W₉ | d₁ = d₃ | d₂ | W₁₀ | d | W₇ | L₇ | W₈ | L₈ |
| Unit (mm) | 1 | 3 | 25 | 2.46 | 8 | 11.5 | 13 | 17 | 12 |

It should be understood, simulation and optimization may be implemented using Ansoft HFSS (High Frequency Structure Simulator) simulator which is a full-wave electromagnetic solver. After optimization, final dimensions of the proposed 1:1.71 microstrip WPD are listed in Table 2 and layout parameters are defined in FIG. 10. It can be fabricated on single-layer microstrip easily. For comparison, dimensions and layout parameters definition of conventional configuration is listed in Table 1 and in FIG. 7.

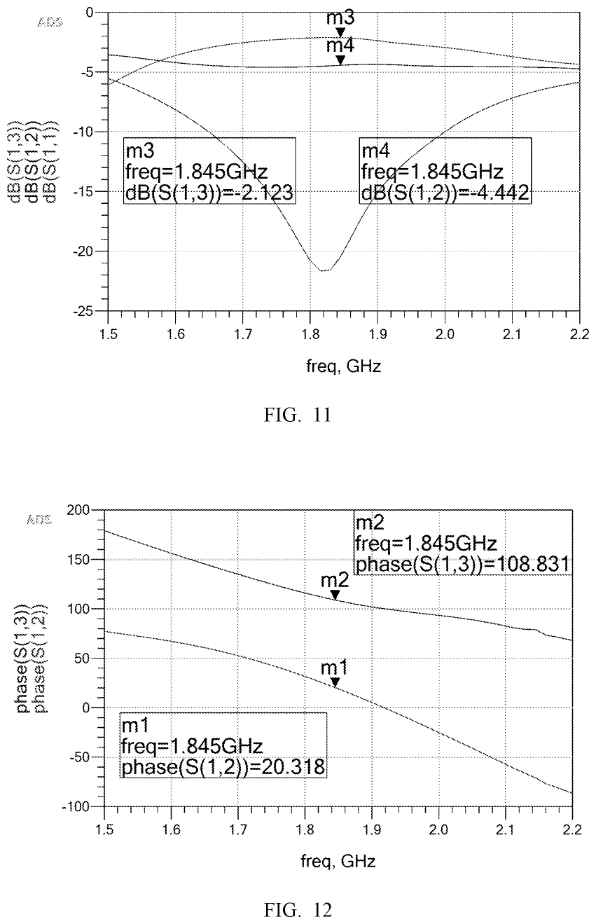

FIG. 11 is an amplitude diagram for the exemplary WPD as shown in FIG. 10.

Two probes on the curves are shown. m3 is a probe on the curve dB(S1,3), and indicates the frequency 1.845 GHz, and a value of dB(S1,3) of −2.123 (very similar to −2.345 of the conventional WPD). m4 is a probe on the curve dB(S1,2), and indicates the frequency 1.845 GHz, and a value of dB(S1,2) of −4.442 (very similar to −4.321 of the conventional WPD).

FIG. 12 is a phase diagram for the exemplary WPD as shown in FIG. 10.

Two probes on the curves are shown. m1 is an probe on the curve phase (S1,2), and indicates the frequency 1.845 GHz, and a value of phase (S1,2) of 20.318. m2 is an probe on the curve phase (S1,3), and indicates the frequency 1.845 GHz, and a value of phase (S1,3) of 108.831.

It can be seen the phase difference of port P2(P2′) and P3 (P3′), which may be presented by “phase (S1,3)-phase (S1,2)”, in the FIG. 12 (108.831-20.318), is very similar to that in the FIG. 9 (46.951-‘−42.15’).

The proposed structure is also applicable to unequal WPD for radio applications. It can reduce the length substantially thus lead to compact size. To validate it, one Doherty application using Wilkinson power divider on single-layer microstrip is designed, and the results prove the validity of this idea. Typically, one conventional WPD consists of power dividing and impedance transforming functionality as FIG. 1 shows and one offset line is needed for Doherty circuit as FIG. 2 illustrates. Here an idea is presented to combine the intrinsic quarter-wave transformers in WPD into the input matching networks (IMNs) of Doherty PA, that is, the quarter-wave transformer of WPD is omitted, thus it substantially reduces the total size compared to conventional configuration. This structure is easy to be implemented in practice. Typically, the size difference of input matching networks matching Zₛ₁ to Z₀ and R_{L1} is minus, thus circuit's layout size can be effectively reduced by using the proposed idea.

With the comparison between the amplitude diagrams and the phase diagrams of the exemplary conventional WPD and the proposed WPD according to embodiments of the present disclosure, it can be seen that the electric features are basically the same, while the size of the proposed WPD are greatly reduced.

Specifically, in embodiments herein, lengths and/or even types of the transmission lines in the power divider may be reduced, and thus the overall size of the power divider and the circuit including the same may be further reduced.

Following specific advantages may be achieved: (1) area-effective, circuit layout size can be reduced substantially, compared to the conventional one since the quarter-wave transformer is saved; (2) lower path loss due to shorter length for power combining applications; (3) cost reduction: the WPD's layout size on PCB is reduced to a great extent compared to the conventional one, thus the occupied area of a high end PCB, such as Rogers 4350B, decreases. It has cost saving due to size reduction. Also, this reduced WPD make it more popular for Doherty application rather than using hybrid coupler from vendors.

It should be understood that there is no limitation for the number of branches/ports of the power divider. Namely, the power divider may divide the power from a source port to more than two reception ports.

Particularly, one technical problem to be solved here is introducing a Wilkinson power dividers (WPDs) for Doherty PA and other power combining applications. Here an idea that incorporates WPD's quarter-wave impedance transforming with transistors' input matching networks is proposed, which leads to a compact structure. Besides, Doherty PA can still be easily tuned via VNA (Vector Network Analyzer) as usual without extra effort. This invention can be widely used in RRHs (remote radio head) for wireless communication systems and 5G massive MIMO products.

The present disclosure includes any novel feature or combination of features disclosed herein either explicitly or any generalization thereof. Various modifications and adaptations to the foregoing exemplary embodiments of this disclosure may become apparent to those skilled in the relevant arts in view of the foregoing description, when read in conjunction with the accompanying drawings. However, any and all modifications will still fall within the scope of the non-limiting and exemplary embodiments of this disclosure.

| Abbreviation | Explanation |
|---|---|
| WPD | Wilkinson Power Divider |
| EM | Electromagnetic |
| PA | Power Amplifier |
| IMN | Input Matching Network |

1. A power divider, comprising: at least two branches;
wherein the at least two branches comprise a first branch coupled between a first port and a second port; and a second branch coupled between the first port and a third port;
wherein the first branch comprises a first transmission line for power dividing function coupled to the first port, and a first impedance matching structure coupled to the second port; and
wherein the second branch comprises a second transmission line for power dividing function coupled to the first port, and a second impedance matching structure coupled to the third port.

2. The power divider according to claim 1,
wherein the first impedance matching structure is constructed at least based on an impedance matching requirement of a first circuit portion following the second port; and
wherein the second impedance matching structure is constructed at least based on an impedance matching requirement of a second circuit portion following the third port.

3. The power divider according to claim 2,
wherein the first impedance matching structure is further constructed to provide impedance transforming between the first transmission line and the first circuit portion; and
wherein the second impedance matching structure is further constructed to provide impedance transforming between the second transmission line and the second circuit portion.

4. The power divider according to claim 2,
wherein the first circuit portion and/or the second circuit portion comprise a power amplifying component.

5. The power divider according to claim 4,
wherein the power amplifying component comprises a transistor.

6. The power divider according to claim 1,
wherein the first impedance matching structure and/or the second impedance matching structure have a planar shape.

7. The power divider according to claim 6,
wherein the first impedance matching structure and/or the second impedance matching structure have a rectangle shape with a width lager than a width of the first transmission line and/or the second transmission line.

8. The power divider according to claim 1,
wherein an impedance of the first transmission line and an impedance of the second transmission line are determined based at least on a power dividing ratio between the second port and the third port.

9. The power divider according to claim 1,
wherein the power divider is a Wilkinson power divider, WPD.

10. A circuit, comprising the power divider,
wherein the power divider, comprises: at least two branches;
wherein the at least two branches comprise a first branch coupled between a first port and a second port; and a second branch coupled between the first port and a third port;
wherein the first branch comprises a first transmission line for power dividing function coupled to the first port, and a first impedance matching structure coupled to the second port; and
wherein the second branch comprises a second transmission line for power dividing function coupled to the first port, and a second impedance matching structure coupled to the third port.

11. The circuit according to claim 10,
wherein the circuit is a Doherty power amplifier;
wherein the power divider functions as an input power splitter of the Doherty power amplifier;
wherein the Doherty power amplifier comprises a first amplifying transistor coupled to the second port, and a second amplifying transistor coupled to the third port; and
wherein the first amplifying transistor has an offsetting requirement for the first branch of the power divider.

12. The circuit according to claim 11,
wherein the first branch further comprises a third transmission line for offsetting function, coupled between the first transmission line and the first impedance matching structure.

13. The circuit according to claim 12,
wherein the third transmission line is constructed at least based on the offsetting requirement of the first amplifying transistor.

14. The circuit according to claim 13,
wherein the third transmission line is further constructed to provide impedance transforming between the first transmission line and the first amplifying transistor.

15. The circuit according to claim 10,
wherein the circuit is a power combining circuit;
wherein the power divider functions as an input power splitter of the power combining circuit;
wherein the power combining circuit comprises a third amplifying transistor coupled to the second port, and a fourth amplifying transistor coupled to the third port.
